(19) United States
(12) Patent Application Publication
(10) Pub. No.: US 2006/0281323 A1
(43) Pub. Date: Dec. 14, 2006

(54) Method of cleaning substrate processing apparatus

(75) Inventors: Tadahiro Ohmi, Miyagi (JP); Masaki Hirayama, Miyagi (JP)

Correspondence Address: FOLEY AND LARDNER LLP;SUITE 500, 3000 K STREET NW, WASHINGTON, DC, 20007, US

(73) Assignee: Tadahiro Ohmi

(21) Appl. No.: 10/555,668

(22) PCT Filed: Apr. 22, 2004
(86) PCT No.: PCT/JP04/05798

§ 371 Date: Dec. 21, 2005

(30) Foreign Application Priority Data
May 8, 2003 (JP) 2003-130543

(51) Int. Cl. H01L 21/302

(52) U.S. Cl. 438/710

(57) ABSTRACT

A method for cleaning a microwave plasma processing apparatus is disclosed wherein a cleaning gas is introduced and then excited with microwave plasma (step 3). By applying high-frequency power to a substrate supporting stage by which a substrate to be processed is supported (step 4), the etching rate is improved, thereby shortening the cleaning time.

### TECHNICAL FIELD

This invention relates generally to a plasma processing apparatus and, in particular, relates to a microwave plasma processing apparatus.

Plasma processing processes and plasma processing apparatuses are the essential technique for the manufacture of ultra-miniaturized semiconductor devices each a so-called deep submicron device or deep subquarter micron device having a gate length approximate to or not greater than 0.1 μm in recent years and the manufacture of high-resolution flat-panel display devices including liquid-crystal display devices.

As the plasma processing apparatuses for use in the manufacture of the semiconductor devices or the liquid-crystal display devices, various plasma exciting types have conventionally been used and, particularly, parallel flat plate type high-frequency excitation plasma processing apparatuses or inductively coupled plasma processing apparatuses are popular. However, these conventional plasma processing apparatuses have a problem that plasma formation is nonuniform and regions of high electron density are limited so that it is difficult to carry out uniform processing over the whole surface of a processing substrate at high processing speed, i.e. high throughput. This problem becomes serious particularly when processing large-diameter substrates. Further, these conventional plasma processing apparatuses have some essential problems like generation of damage to a semiconductor element formed on a processing substrate due to high electron temperature, large metal contamination due to sputtering of a processing chamber wall, and so on. Therefore, with the conventional plasma processing apparatuses, it is getting difficult to satisfy strict demands for further miniaturization and further improvement in productivity of the semiconductor devices or the liquid-crystal display devices.

On the other hand, there have conventionally been proposed microwave plasma processing apparatuses each not using a DC magnetic field but using a high-density plasma excited by a microwave electric field. For example, there has been proposed a plasma processing apparatus having a structure where a microwave is radiated into a processing container from a planar antenna (radial line slot antenna) having a number of slots arranged so as to generate a uniform microwave, thereby ionizing a gas in the vacuum container by the use of the microwave electric field to excite a plasma.

With the microwave plasma excited by such a technique, the high plasma density can be realized over a wide region right under the antenna so that it is possible to implement uniform plasma processing in a short time. Further, with the microwave plasma formed by such a technique, it is possible to avoid damage to and metal contamination of a processing substrate because of a low electron temperature since the plasma is excited by the microwave. Moreover, since a uniform plasma can be easily-excited even on a large-area substrate, it is also possible to easily cope with the manufacturing process of a semiconductor device using a large-diameter semiconductor substrate or the manufacture of a large-size liquid-crystal display device.

### BACKGROUND ART

FIGS. 1, (A) and (B) show a structure of a conventional plasma processing apparatus 100 using such a radial line slot antenna, wherein FIG. 1, (A) is a sectional view of the plasma processing apparatus 100 and FIG. 1, (B) is a diagram showing a structure of the radial line slot antenna.

Referring to FIG. 1, (A), the plasma processing apparatus 100 has a processing container 101 which is evacuated through a plurality of exhaust ports 116, and a holding stage 115 for holding a processing substrate 114 is provided in the processing container 101. For realizing uniform evacuation of the processing container 101, a space 101A is formed in a ring shape around the holding stage 115 and, by forming the plurality of exhaust ports 116 at regular intervals, i.e. axisymmetrically with respect to the processing substrate, so as to communicate with the space 101A, the processing container 101 can be uniformly evacuated through the space 101A and the exhaust ports 116.

A plate-shaped shower plate 103 made of a low-loss dielectric and formed with a number of opening portions 107 is provided on the processing container 101 through a seal ring 109 as part of the outer wall of the processing container 101 at a position corresponding to the processing substrate 114 on the holding stage 115. Further, a cover plate 102 also made of a low-loss dielectric is provided on the outer side of the shower plate 103 through another seal ring 108. The shower plate 103 transmits a microwave therethrough and thus is called a microwave transmissive window.

The shower plate 103 has a plasma gas passage 104 formed on its upper surface and the plurality of opening portions 107 are each formed so as to communicate with the plasma gas passage 104. Further, inside the shower plate 103 is formed a plasma gas supply passage 106 communicating with a plasma gas supply port 105 provided in the outer wall of the processing container 101. A plasma gas such as Ar or Kr supplied to the plasma gas supply port 105 is supplied to the opening portions 107 through the supply passage 106 and the passage 104 and discharged from the opening portions 107 into a space 101B right under the shower plate 103 inside the processing container 101 at a substantially uniform concentration.

A radial line slot antenna 110 having a radiating surface shown in FIG. 1, (B) is further provided on the outer side of the cover plate 102 on the processing container 101 so as to be spaced apart from the cover plate 102 by 4 to 5 mm. The radial line slot antenna 110 is connected to an external microwave source (not shown) through a coaxial waveguide 110A so that the plasma gas discharged into the space 101B is excited by a microwave from the microwave source. A gap between the cover plate 102 and the radiating surface of the radial line slot antenna 110 is filled with the atmosphere.

The radial line slot antenna 110 comprises a flat disk-shaped antenna body 110B connected to an outer waveguide of the coaxial waveguide 110A, and a radiating plate 110C provided at an opening portion of the antenna body 110B and formed with a number of slots 110a and a number of slots 110b perpendicular thereto as shown in FIG. 1, (B). A phase delay plate 110D in the form of a dielectric plate having a constant thickness is inserted between the antenna body 110B and the radiating plate 110C.

In the radial line slot antenna 110 having such a structure, the microwave fed from the coaxial waveguide 110A proceeds while spreading radially between the disk-shaped antenna body 110B and the radiating plate 110C and, in this event, the wavelength thereof is compressed due to the function of the phase delay plate 110D. Therefore, by forming the slots 110a and 110b so as to be concentric and perpendicular to each other corresponding to the wavelength of the microwave proceeding radially as described above, a plane wave having circular polarization can be radiated in a direction substantially perpendicular to the radiating plate 110C.

By the use of the radial line slot antenna 110, a uniform high-density plasma is formed in the space 101B right under the shower plate 103. The high-density plasma thus formed has a low electron temperature so that there is no occurrence of damage to the processing substrate 114 and there is no occurrence of metal contamination due to sputtering of the wall of the processing container 101.

The plasma processing apparatus 100 of FIG. 1 is further provided with a process gas supply portion 111 in the processing container 101 between the shower plate 103 and the processing substrate 114. The process gas supply portion 111 is formed with a number of nozzles 113 that supply a process gas from an external process gas source (not shown) through a process gas passage 112 formed in the processing container 101. The nozzles 113 each discharge the supplied process gas into a space 101C between the process gas supply portion 111 and the processing substrate 114. Between the adjacent nozzles 113 and 113 of the process gas supply portion 111, there are formed opening portions each having a size that can efficiently pass therethrough the plasma, formed in the space 101B, from the space 101B into the space 101C by diffusion.

Accordingly, when the process gas is discharged into the space 101C from the process gas supply portion 111 through the nozzles 113 as described above, the discharged process gas is excited by the high-density plasma formed in the space 101B so that uniform plasma processing is achieved on the processing substrate 114 efficiently and at high speed, and further, without damaging the substrate and an element structure on the substrate and without contaminating the substrate. On the other hand, the microwave radiated from the radial line slot antenna 110 is obstructed by the process gas supply portion 111 made of a conductor and thus is prevented from damaging the processing substrate 114.

As the substrate processing that can be implemented by the plasma processing apparatus 100, there is a plasma oxidation process, a plasma nitriding process, a plasma oxynitriding process, a plasma CVD process, or the like. By supplying an etching gas to the space 101B from the nozzles 113 of the process gas supply portion 111 and by applying a high-frequency voltage to the holding stage 115 from a high-frequency power supply 115A, it is also possible to perform reactive ion etching to the processing substrate 114.

When the film formation process such as the plasma CVD process is implemented for carrying out film formation on the processing substrate 114 by the use of the plasma processing apparatus 100, deposits are deposited inside the processing container 101 during the film formation. For example, when the film formation is carried out over a long time so that the deposits are accumulated, the deposits are stripped from the deposited portion to thereby cause generation of particles or the like.

Therefore, it is necessary to perform cleaning for removing the deposits regularly. The plasma processing apparatus as described above and its cleaning method are described, for example, in Japanese Unexamined Patent Application Publication (JP-A) No. H9-63793, Japanese Unexamined Patent Application Publication (JP-A) No. 2002-57106, and Japanese Unexamined Patent Application Publication (JP-A) No. 2002-57149.

For example, when performing the cleaning, there is a method of introducing a cleaning gas from the shower plate 103 and performing microwave plasma excitation to dissociate the cleaning gas, thereby etching the deposits to remove them.

However, in the case of such cleaning using the microwave plasma, there are instances where the deposits cannot be completely removed or the etching rate for the removal is slow so that much time is required for the cleaning.

For example, at the portion under the process gas supply portion 111, i.e. in the space 101C, the microwave plasma is not excited because the microwave cannot reach here and, further, since only the plasma diffused from the space 101B exists, the plasma density is low and the electron temperature is low.

Therefore, there arises a problem that the deposits deposited at portions facing the space 101C are not etched or the etching rate thereof is slow in the case of the foregoing cleaning using the microwave plasma.

Specifically, with respect to the deposits on the side, facing the space 101C, of the process gas supply portion 111 and the deposits at portions, facing the space 101C, of the inner wall surface of the processing container 101, the etching rate is slow and, with respect also to the deposits on the wall surface on the holding stage 115 side, it is difficult to completely clean them.

Therefore, it is an object of this invention to provide a new and useful method of cleaning a substrate processing apparatus, which solves the foregoing problems.

A specific object of this invention is to provide a new substrate processing apparatus cleaning method that can shorten the cleaning time by efficiently carrying out cleaning in a substrate processing apparatus using a microwave plasma.

### DISCLOSURE OF THE INVENTION

According to this invention, in a substrate processing apparatus using a microwave, by using a microwave plasma and applying a high-frequency power to a holding stage of a processing substrate at the time of cleaning for removing a deposit deposited during film formation, it becomes possible to increase the etching rate of the deposit to thereby shorten the cleaning time.

### BRIEF DESCRIPTION OF THE DRAWINGS

FIG. 1 is a diagram showing an outline of a plasma processing apparatus.

FIG. 2 is a flowchart showing a substrate processing apparatus cleaning method according to this invention.

FIG. 3 is a diagram showing, in simulation, the state where a microwave plasma is excited in the plasma processing apparatus of FIG. 1.

FIG. 4 is a diagram showing the cleaning rates according to the substrate processing apparatus cleaning method of this invention.

### BEST MODE FOR CARRYING OUT THE INVENTION

Now, an embodiment of this invention will be described in detail.

### FIRST EMBODIMENT

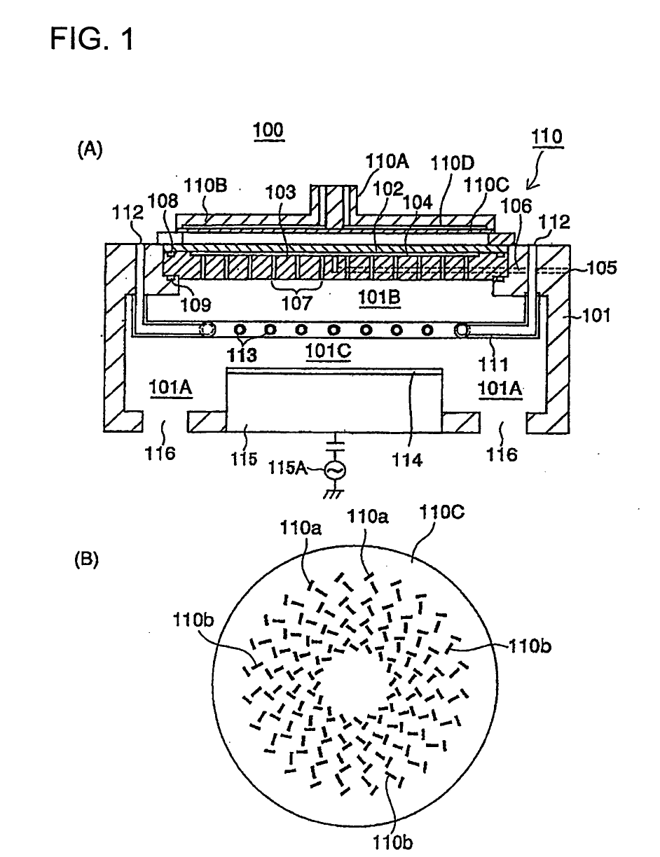

At first, a specific example will be shown below, wherein film formation is performed on the processing substrate 114 by carrying out the plasma CVD process as an example of the substrate processing by the use of the foregoing plasma processing apparatus 100 described with reference to FIG. 1.

In the case of the plasma processing apparatus 100, when forming an insulating film on the processing substrate 114 by the plasma CVD process, it is possible to form a silicon oxide film (SiO₂ film) by using O₂ and Ar as a plasma gas and SiH₄ as a process gas or, likewise, a nitride film (SiN film) by using N₂ and Ar as a plasma gas and SiH₄ as a process gas.

Further, likewise, it is possible to form a fluorine-added carbon film (CxFy film) by using Ar and H₂ as a plasma gas and a fluorocarbon-based gas, for example, C₄F₈, as a process gas.

When the film formation process as described above is implemented, the foregoing silicon oxide film, nitride film or fluorine-added carbon film is deposited as deposits in the processing container 101 like on the processing substrate 114.

When the deposits are accumulated, the deposits are stripped from the inner part of the processing container 101 to cause generation of particles and, therefore, it is necessary to carry out the cleaning regularly. Accordingly, a cleaning method according to this invention is implemented to clean the inside of the processing container 101, thereby removing the deposits.

Now, a specific cleaning method for the plasma processing apparatus 100 will be shown below.

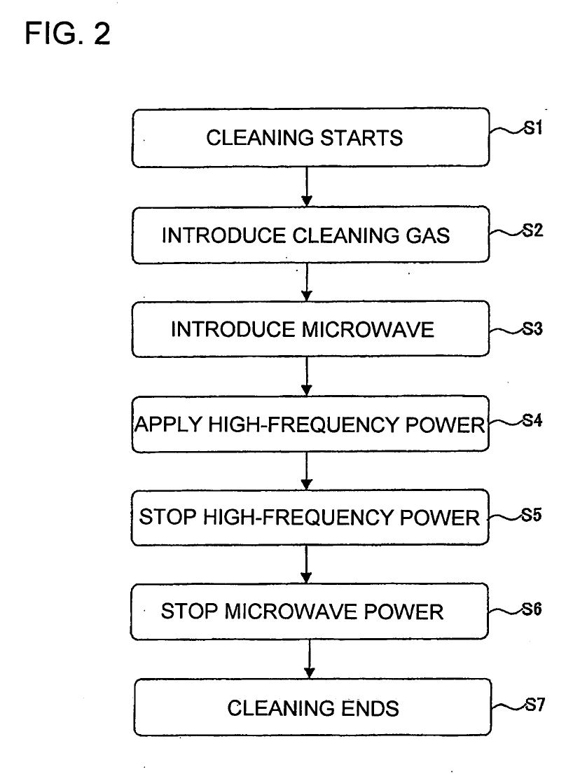

FIG. 2 is a flowchart showing a substrate processing apparatus cleaning method according to a second example of this invention. In this example, description will be made about the method of cleaning the foregoing fluorine-added carbon film.

Referring to FIG. 2, when, at first, a cleaning process is started in step 1 (indicated as S1 in the figure; the same shall apply hereinafter), a cleaning gas is introduced into the processing container 101 in step 2. When cleaning a fluorine-added carbon film, use is made of, for example, O₂ and H₂ as the cleaning gas. There are cases where Ar is further used as a diluent gas for diluting the cleaning gas such as O₂ and H₂ to achieve uniform etching in the processing container 101 by the cleaning gas and facilitating plasma excitation.

Accordingly, in step 2, 100/100/800 sccm of O₂/H₂/Ar, respectively, are introduced into the space 101B through the opening portions 107 of the shower plate 103.

Then, in step 3, a microwave power of 1400 W is introduced to the radial line slot antenna 110 from the microwave power supply, thereby exciting a microwave plasma in the processing container 101.

Since the microwave plasma is excited in this step, introduced O₂/H₂ are dissociated so that reactive species such as oxygen radicals, hydrogen radicals, oxygen ions, and hydrogen ions that contribute to etching of the fluorine-added carbon film are produced to thereby etch the fluorine-added carbon film being the deposits in the processing container 101 in the following manner and, thus, the substantial cleaning is started.

$$CxFy + \frac{x}{2} {O}_{2} + \frac{y}{2} {H}_{2} ⇒ x C O ↑ + y H F ↑$$

In this step, by adding H₂O as a cleaning gas in addition to O₂/H₂, it is possible to accelerate the formation of oxygen radicals, hydrogen radicals, oxygen ions, and hydrogen ions that contribute to the etching to thereby further improve the cleaning rate.

However, only by the foregoing cleaning using the microwave plasma, there are cases where the etching rate for removal of the fluorine-added carbon film is slow so that much time is required for the cleaning.

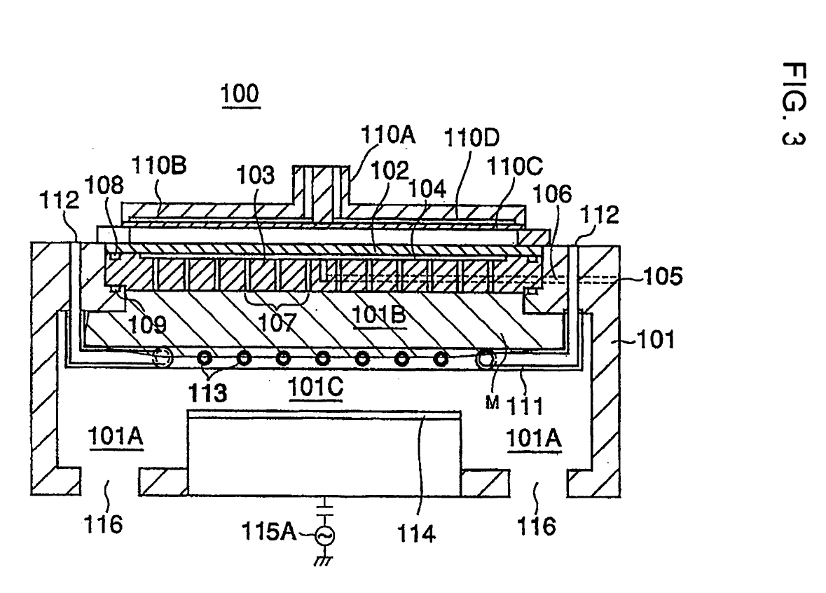

FIG. 3 shows, in simulation, the state where a microwave plasma M is excited in the plasma processing apparatus 100. In the figure, the same reference symbols are assigned to those portions described before, thereby omitting description thereof.

Referring to FIG. 3, for example, at the portion under the process gas supply portion 111, i.e. in the space 101C, the microwave plasma is not excited because the microwave cannot reach here and, further, since only the plasma diffused from the space 101B exists, the plasma density is low and the electron temperature is low.

Therefore, there arises a problem that the deposits deposited at portions facing the space 101C are not etched or the etching rate thereof is slow in the case of the foregoing cleaning using only the microwave plasma.

Specifically, with respect to the deposits on the side, facing the space 101C, of the process gas supply portion 111 and the deposits at portions, facing the space 101C, of the inner wall surface of the processing container 101, the etching rate is slow and, with respect also to the deposits on the wall surface on the holding stage 115 side, it is difficult to completely clean them.

In view of this, in the substrate processing apparatus cleaning method according to this invention, next in step 4, a high-frequency power of 300 W is applied to the holding stage 115 from the high-frequency power supply 115A connected to the holding stage 115. The frequency of the high-frequency power supply used in this example is 2 MHz, while, use may be made of a frequency of 500 MHz or less, preferably 100 kHz to 15 MHz. Further, a DC bias may also be used.

In this step, since the high-frequency power is applied to the substrate holding stage 115, the plasma potential oscillates so that the plasma potential of the space 101C is raised.

Since the high-frequency plasma is excited in the space 101C, the dissociation of the cleaning gas proceeds to thereby produce reactive species such as radicals and ions necessary for etching the deposits and further the plasma potential is raised, the ion energy incident on the cleaning-object wall surface increases so that the etching of the deposits is accelerated.

As a result, an effect is obtained that the etching rate is improved with respect to the deposits on the side, facing the space 101C, of the process gas supply portion 111, the deposits at the portions, facing the space 101C, of the inner wall surface of the processing container 101, and the deposits on the wall surface on the holding stage 115 side and, therefore, the cleaning rate is improved.

Then, when the etching of the deposits is completed, the introduction of the high-frequency power and the microwave power is stopped in steps 5 and 6, respectively, and the cleaning ends in step 7.

In this example, the cleaning gas and the diluent gas are introduced through the shower plate 103. However, according to necessity, it is possible to introduce them, for example, through both the shower plate 103 and the process gas supply portion 111, or only through the process gas supply portion 111. Further, it is also possible to change the proportion of the introduction from the shower plate 103 and the process gas supply portion 111.

For example, the cleaning gas can be efficiently used according to the film forming conditions of the fluorine-added carbon film by increasing the proportion of the flow rate of the cleaning gas and the diluent gas introduced from the shower plate 103 when the deposits at the portions facing the space 101B are large in quantity, while, increasing the proportion of the flow rate of the cleaning gas and the diluent gas introduced from the process gas supply portion 111 when the deposits at the portions facing the space 101C are large in quantity. As a result, more efficient cleaning is enabled that suppresses the amount of use of the cleaning gas and, further, that improves the cleaning rate.

In order to confirm that the removal of the deposits in the processing container 101 has been completed and thus the cleaning has been finished, there is a method of monitoring the plasma emission state. For example, a change in intensity of the light having a specific wavelength is monitored by implementing spectral processing of emission during the cleaning by the use of a spectrometer or the like, thereby detecting an end point of the cleaning by determining that the cleaning is finished at a time instant when the change in emission intensity converges.

Further, it becomes possible to efficiently improve the cleaning rate according to the deposition state of the cleaning-object deposits, for example, by increasing the time of application of the high-frequency power when the deposits at the portions facing the space 101C are large in quantity.

Moreover, it becomes possible to perform efficient cleaning according to the amount of the deposits by changing the time of introduction of the microwave power and the time of introduction of the high-frequency power, and the timing of introducing/stopping the microwave power and the timing of introducing/stopping the high-frequency power according to necessity. It is also possible to carry out the cleaning only by the high-frequency plasma with the high-frequency power according to necessity.

In the example so far, the method of cleaning the fluorine-added carbon film is shown. However, it is also possible to clean an insulating film such as a silicon oxide film (SiO₂ film), a fluorine-added silicon oxide film (SiOF film), or a silicon nitride film (SiN film) by the use of the same method.

With respect to the foregoing SiO₂ film, SiOF film or SiN film, it is possible to implement the cleaning according to the method shown in FIG. 2 by using a fluorine compound gas, for example, NF₃, CF₄, C₂F₆, SF₆, or the like as a cleaning gas and it is possible to obtain the same effect as in the case of cleaning the fluorine-added carbon film.

Further, for example, in the case of cleaning deposits in which a fluorine-added carbon film and a SiO₂ film, SiOF film or SiN film are stacked in layers or in the case of cleaning deposits in which an inorganic insulating film such as a SiCO film or a SiCO(H) film and an organic insulating film are mixedly present, the cleaning can be implemented by using a mixed gas of NF₃, O₂, H₂, and H₂O as a cleaning gas or by alternately performing cleaning with NF₃ and cleaning with O₂, H₂, and H₂O. Also in this case, it is possible to obtain the same effect as in the foregoing case of cleaning the fluorine-added carbon film.

### SECOND EMBODIMENT

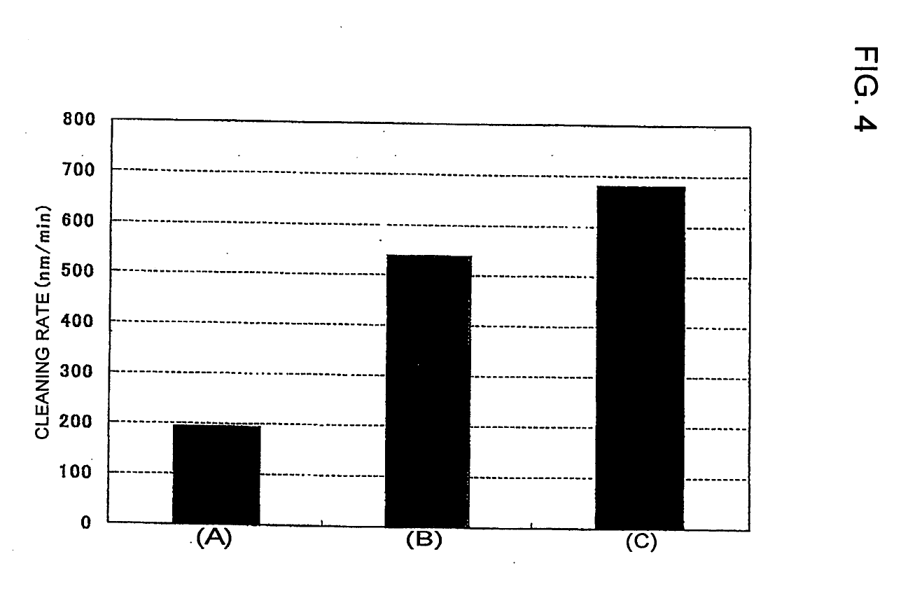

Now, FIG. 4 shows the cleaning rates when the cleaning is carried out by the use of the substrate processing apparatus cleaning method shown in FIG. 2, which has been described in the first example. In the following description, when described before, the same reference symbols are used to thereby omit description.

FIG. 4 shows the cleaning rates when the cleaning of the fluorine-added carbon film is carried out according to the method described in the first example, wherein the results are shown in the case (B) where the high-frequency power to the holding stage 115 is set to 300 W and in the case (C) where it is set to 500 W. Further, for comparison, the results are also shown in the case (A) where the cleaning is carried out only by the microwave plasma without applying the high-frequency power to the holding stage 115.

Referring to FIG. 4, in the case (A) where the cleaning is performed only by the microwave plasma, the cleaning rate is 194 nm/min, while, in the case (B) of applying the high-frequency power of 300 W, the cleaning rate becomes 540 nm/min and therefore the cleaning rate becomes 2.8 times as compared with the case (A) where the high-frequency power is not applied. Further, in the case (C) where the high-frequency power is set to 500 W, the cleaning rate becomes 680 nm/min and thus becomes 3.5 times as compared with the case (A) where the high-frequency power is not applied so that the cleaning time can be further shortened.

This is because, as described before, it is considered that, by applying the high-frequency power to the holding stage 115, the effect is obtained that the etching rate is improved with respect to the deposits on the side, facing the space 101C, of the process gas supply portion 111, the deposits at the portions, facing the space 101C, of the inner wall surface of the processing container 101, and the deposits on the wall surface on the holding stage 115 side and, therefore, the cleaning rate increases.

On the other hand, in order to protect the surface of the holding stage 115, the cleaning may be carried out, for example, after placing a protective wafer made of sintered ceramic such as Al₂O₃ or SiN on the holding stage 115.

The foregoing cleaning can be carried out every time the film formation process is finished for a single processing substrate, but it is also possible to carry out the cleaning, for example, every time the film formation process is finished for a plurality of processing substrates.

While this invention has been described in terms of the preferred examples, this invention is not to be limited to the foregoing specific examples and various modifications and changes can be made within the gist as recited in claims.

### INDUSTRIAL APPLICABILITY

According to this invention, in the substrate processing apparatus using a microwave plasma that can easily excite a uniform plasma even on a large-area substrate, the cleaning time can be shortened by efficiently carrying out the cleaning. In view of this, this invention is suitable for use in the manufacturing process of semiconductor devices using large-diameter semiconductor substrates or the manufacturing process of large-size liquid-crystal display devices.

1. A method of cleaning a substrate processing apparatus comprising a processing container defined by an outer wall, a holding stage connected to a high-frequency power supply and provided in said processing container for holding a processing substrate, an exhaust port for evacuating the inside of said processing container, a microwave transmissive window provided on said processing container as part of said outer wall so as to face said processing substrate, a microwave antenna provided on said microwave transmissive window and electrically connected to a microwave power supply, a plasma gas supply portion for supplying a plasma gas into said processing container, and a process gas supply portion provided between said processing substrate on said holding stage and said microwave transmissive window so as to face said processing substrate, said method comprising:
a gas introducing step of introducing a cleaning gas into said processing container,
a plasma exciting step of introducing a microwave into said processing container from said microwave antenna to thereby excite a plasma in said processing container, and
a bias applying step of applying a high-frequency power to said holding stage from said high-frequency power supply.

2. The method according to claim 1, wherein said process gas supply portion is made of a conductive material and grounded.

3. The method according to claim 1, wherein said microwave antenna is power-fed through a coaxial waveguide and comprises an antenna body having an opening portion, a microwave radiating surface having a plurality of slots and provided on said antenna body so as to cover said opening portion, and a dielectric provided between said antenna body and said microwave radiating surface.

4. The method according to claim 1, wherein said cleaning gas contains oxygen.

5. The method according to claim 1, wherein said cleaning gas contains hydrogen.

6. The method according to claim 1, wherein said cleaning gas contains H₂O.

7. The method according to claim 1, wherein said cleaning gas contains a fluorine compound.

8. The method according to claim 1, wherein said cleaning gas is introduced from said plasma gas supply portion provided between said microwave antenna and said process gas supply portion.

9. The method according to claim 1, wherein said cleaning gas is introduced from said process gas supply portion.

10. The method according to claim 1, wherein said cleaning gas is dissociated by said microwave plasma and a high-frequency plasma excited by said high-frequency power so as to be reactive species, and a deposit deposited inside said processing container is etched by said reactive species so as to be removed.

11. The method according to claim 10, wherein said deposit contains a fluorine-added carbon film.
